(19) United States
(12) Patent Application Publication
(10) Pub. No.: US 2012/0302070 A1
(43) Pub. Date: Nov. 29, 2012

(54) METHOD AND SYSTEM FOR PERFORMING PULSE-ETCHING IN A SEMICONDUCTOR DEVICE

(75) Inventors: Chih Ching Lin, Taoyuan City (TW); Yi Nan Chen, Taipei City (TW); Hsien Wen Liu, Luzhu Township (TW)

(73) Assignee: NANYA TECHNOLOGY CORPORATION, Kueishan (TW)

(21) Appl. No.: 13/116,209

(22) Filed: May 26, 2011

(51) Int. Cl. H01L 21/3065; C23F 1/08

(52) U.S. Cl. 438/710; 156/345.28; 257/E21.218

(57) ABSTRACT

A method for performing pulse-etching in a semiconductor device includes the steps of providing a semiconductor substrate, wherein a metal layer is disposed on the semiconductor substrate, and a hard mask layer is blanketed over the metal layer; introducing the semiconductor substrate into a processing container; introducing, into the processing container, etching gases in which a deposition-type gas composed of at least two of C, H, and F is added to etching gas selected from the group consisting of Cl₂ gas, BCl₃ gas, HBr gas, and the combination thereof; applying a pulse-modulated high-frequency voltage between a pair of electrodes that are provided in the processing container so as to be opposed to each other and to hold the semiconductor substrate, such that the high-frequency voltage is turned on and off to establish a duty ratio; generating a plasma between the pair of electrodes; and etching the semiconductor substrate using the plasma.

### TECHNICAL FIELD

The present invention relates to a method and a system for performing pulse-etching. More particularly, the present invention relates to a method and a system for performing pulse-etching in a semiconductor device.

### BACKGROUND

In the fabrication of semiconductor integrated circuits, metal lines are to often employed as conductive paths between the devices on the integrated circuit. To form the metal lines, a metal layer is typically blanket deposited over the surface of the wafer. Using an appropriate photoresist mask, portions of the metal layer are then etched away, leaving behind metal lines.

As the density of integrated circuits increases and the line width decreases, a variety of techniques has been developed to properly etch the shrinking line-width of the integrated circuit. One of these techniques involves plasma-enhanced etching, which is a dry-etching process. During the etching of the metal layer, the photoresist mask protects the portions of the metal layer disposed below the photoresist, thereby forming the metal line pattern including at least one via structure.

When the etching is performed in accordance with a plasma-enhanced process known as reactive ion etching (RIE), polymer materials such as sputtered photoresist can protect the side wall of the via structure from side-etchings or bowing trench effects.

In some types of semiconductor fabrication, a hard mask is used in addition to the customary photoresist for patterning. The photoresist is initially patterned, and then a hard mask under the photoresist is etched to form corresponding line patterns. Since the material of the hard mask is usually SiO₂, the polymer materials for protecting from side-etching is rarely formed, causing the bowing trench effect to be more severe.

Moreover, reactive ion etching lag or RIE lag is a frequently seen defect in semiconductor fabrication processes when etching of a line in silicon or silicon oxide is desired. The RIE lag defect affects the etching dimension uniformity and thus the quality of the fabricated device. The RIE lag phenomenon often occurs during a dry etching process or a reactive ion etching process. The RIE lag effect becomes more severe as the line width becomes smaller.

Accordingly, there is a need for a method and a system to resolve the above-mentioned defects occurring in a dry-etching process in a semiconductor device having a hard mask.

### SUMMARY

To solve the problems of the above-mentioned prior art, the present invention discloses a method for performing pulse-etching in a semiconductor device. The method comprises the following steps of A method for performing pulse-etching in a semiconductor device includes the steps of providing a semiconductor substrate, wherein a metal layer is disposed on the semiconductor substrate, and a hard mask layer is blanketed over the metal layer; introducing the semiconductor substrate into a processing container; introducing, into the processing container, etching gases in which a deposition-type gas composed of at least two of C, H, and F is added to etching gas selected from the group consisting of Cl₂ gas, BCl₃ gas, HBr gas, and the combination thereof; applying a pulse-modulated high-frequency voltage between a pair of electrodes that are provided in the processing container so as to be opposed to each other and to hold the semiconductor substrate, such that the high-frequency voltage is turned on and off to establish a duty ratio; generating a plasma between the pair of electrodes; and etching the semiconductor substrate using the plasma.

In addition, the present invention discloses a system for performing pulse-etching in a semiconductor device. The system comprises a processing container, a flow controller, and a high-frequency power module. The processing container includes a top wall, a bottom wall, an evacuation outlet, a vacuum pressure setting valve, a pair of opposed electrodes, and a plurality of gas introduction inlets. The top wall is disposed corresponding to the bottom wall, below which the evacuation outlet is disposed. The vacuum pressure setting valve controls the evacuation outlet for maintaining a vacuum pressure in the processing container. A pair of opposed electrodes are disposed on the top wall and the bottom wall, respectively. The gas introduction inlets are disposed in the electrode disposed on the top wall and introduce etching gases into a space between the top wall and the bottom wall. The flow controller controls a flow rate of the etching gases. The high-frequency power module applies a high-frequency voltage between the electrodes, such that the high-frequency voltage is turned on and off to establish a duty ratio.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIG. 1 shows a configuration of an etching system according to one embodiment of the present invention in which a voltage having a pulse waveform is applied;

FIG. 2 shows an embodiment of a bias voltage generated on an etching sample by application of a pulse waveform voltage;

FIG. 3 shows a particular embodiment of a pulse modulation when a pulse waveform voltage is applied;

FIG. 4 shows an example of etched shapes obtained by an etching method in which the traditional etching system is used;

FIG. 5 shows an embodiment of etched shapes obtained by an etching system of FIG. 1 of the present invention in which a pulse waveform voltage and deposition-type gas are used; and

FIG. 6 shows a flow chart of a method for performing pulse-etching according to one embodiment of the present invention in which a voltage having a pulse waveform is applied.

### DETAILED DESCRIPTION

Some preferred embodiments of the present invention will be described with reference to the accompanying drawings, in which like reference numerals designate same or corresponding portions.

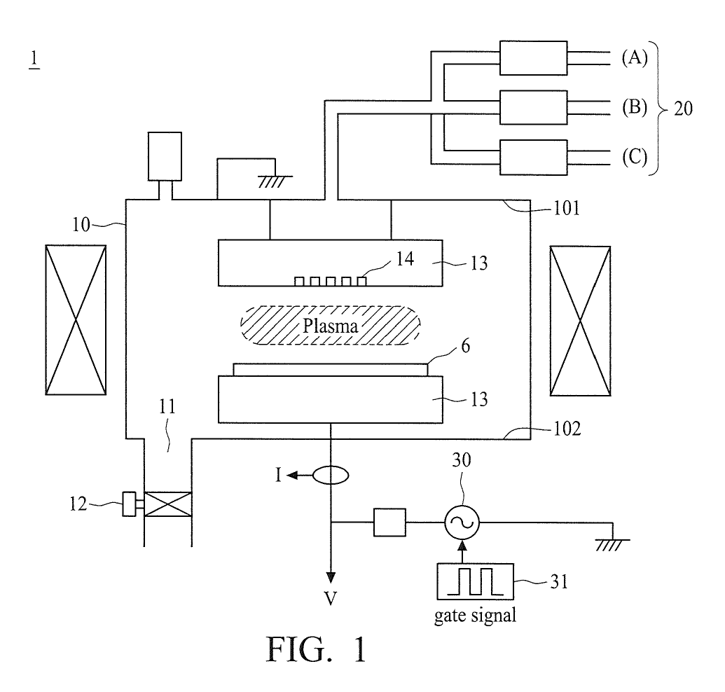

FIG. 1 shows a configuration of an etching system 1 according to one embodiment of the present invention. The system 1 for performing pulse-etching in a semiconductor device is applied by a voltage having a pulse waveform. As shown in FIG, 1, the system 1 comprises a processing container 10, at least one flow controller 20, and a high-frequency power module 30. The processing container 10 includes a reaction processing space defined by a top wall 101 and a bottom wall 102 disposed corresponding to the top wall 101. In addition, the processing container 10 further includes an evacuation outlet 11, a vacuum pressure setting valve 12, a pair of opposed electrodes 13, and a plurality of gas introduction inlets 14. The evacuation outlet 11 is disposed below the bottom wall 102 and allows the etched particles to be evacuated for maintaining the vacuum pressure. In addition, the vacuum pressure setting valve 12 controls the evacuation outlet 11 so as to maintain the pressure at a predetermined level. The gas introduction inlets 14, introducing etching gases into the reaction processing space between the top wall 101 and the bottom wall 102, are disposed in the electrode 13 disposed on the top wall 101. A sample 6 is to be etched. Top and bottom electrodes 13 work to generate a plasma. The pair of opposed electrodes 13, on which a pulse-modulated voltage is applied, are disposed on the top wall 101 and the bottom wall 102, respectively. The high-frequency power module 30 applies a high-frequency voltage between the electrodes 13. In the embodiment shown in FIG. 1, the flow controllers 20 control the flow rates of etching gases to be introduced. Although there are three flow controllers 20 in this embodiment, in another embodiment (not shown), only one flow controller still can perform similar function. In addition, the high-frequency power module 30 further includes a control signal generator 31, which controls the voltage and the discharge period of the pulse-modulated voltage.

Etching gases A and B, whose flow rates are set by the respective flow controllers 20, are introduced into the processing container 10 through the gas introduction inlets 14. In this embodiment, the etching gases A and B are Cl₂ and BCl₃, respectively. However, in another embodiment (not shown), the etching gas can be selected from a Cl₂ gas, a BCl₃ gas, an HBr gas, and a mixture thereof.

Supplied with a voltage from the high-frequency power module 30, the top and bottom electrodes 13 form a capacitor via the sample 6 to be etched. The control signal generator 31 of the high-frequency power module 30 supplies RF power, which is applied to the top and bottom electrodes 13, such that the high-frequency voltage is turned on and off to establish a duty ratio. The high-frequency voltage is applied between the pair of electrodes 13, which are turned on and off at a modulation frequency in a range between 1 Hz and 50 kHz.

With the above etching system 1, a plasma is generated between the top and bottom electrodes 13 by applying a pulse-modulated high-frequency voltage from the high-frequency power module 30. Ions of the plasma are introduced to the surface of the sample 6 to be etched, such as a semiconductor substrate, and the sample 6 is etched by chemical reactions and sputtering.

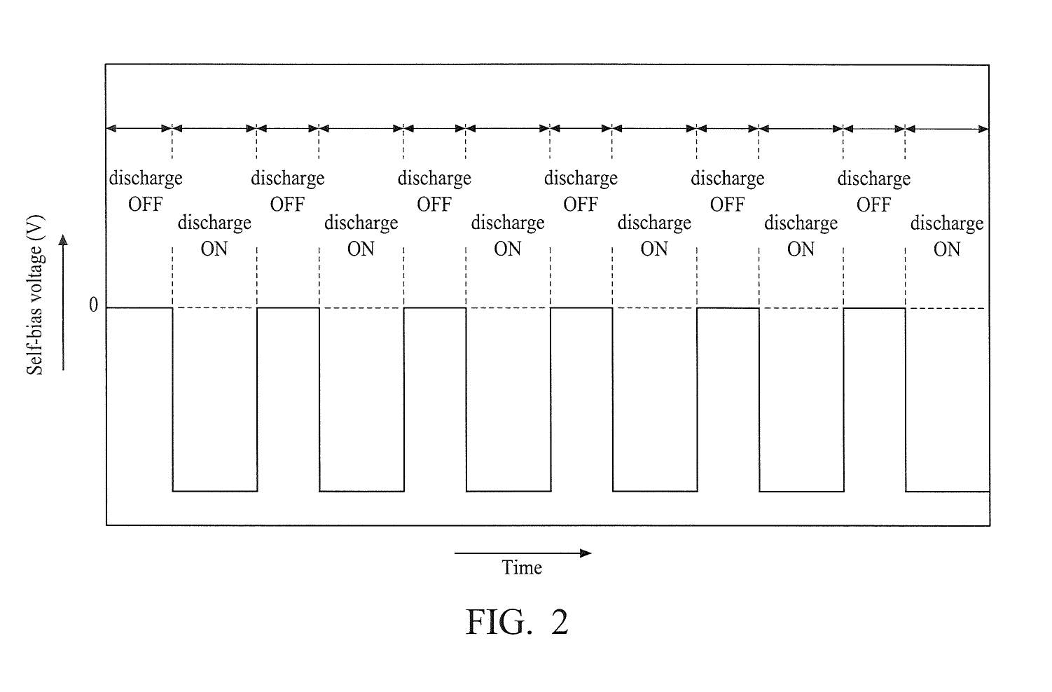

FIG. 2 shows that a bias voltage is generated on an etching sample 6 by application of a pulse waveform voltage. Since discharge-on and discharge-off states are established alternately and repeatedly, in a discharge-off state the energy of positive ions as charged particles decreases and etching is performed by only a Cl radical component. In a discharge-on state, the energy of negative ions as Cl⁻ decreases.

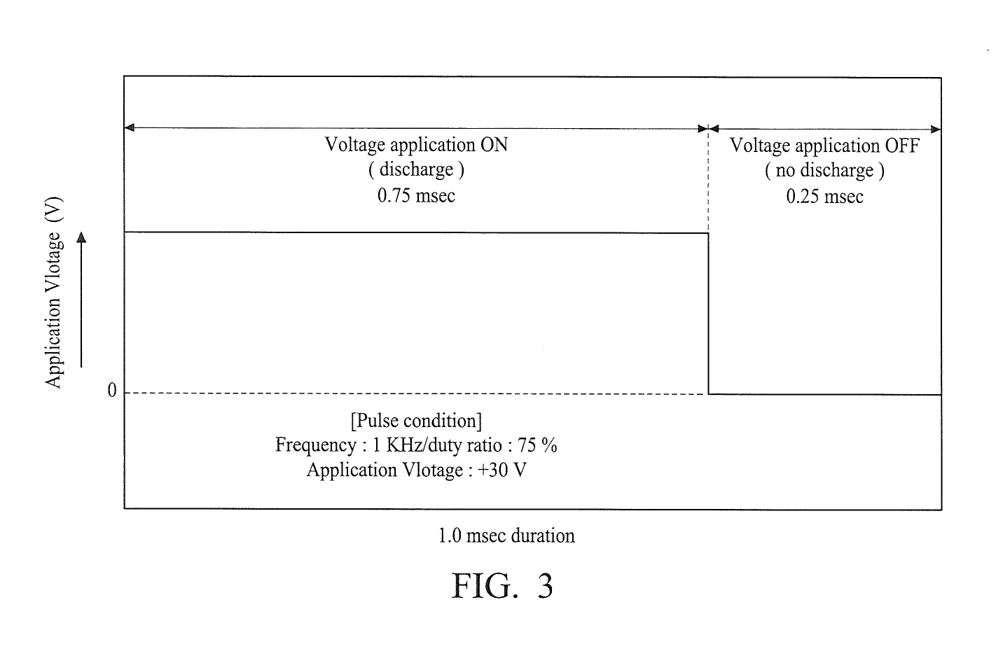

FIG. 3 shows a more specific example of a manner of pulse modulation in an etching method using a pulse waveform voltage. The duty ratio refers to a ratio of the discharge period to the entire period that consists of the discharge period (voltage application ON) and the suspension period (voltage application OFF), that is, (duty ratio)=(discharge period)/(discharge period plus suspension period). In the embodiment shown in FIG. 3, pulsed discharges having a pulse frequency 1 kHz and a duty ratio 75%, a discharge period of 0.75 microsecond (msec), and suspension period of 0.25 microsecond are repeated.

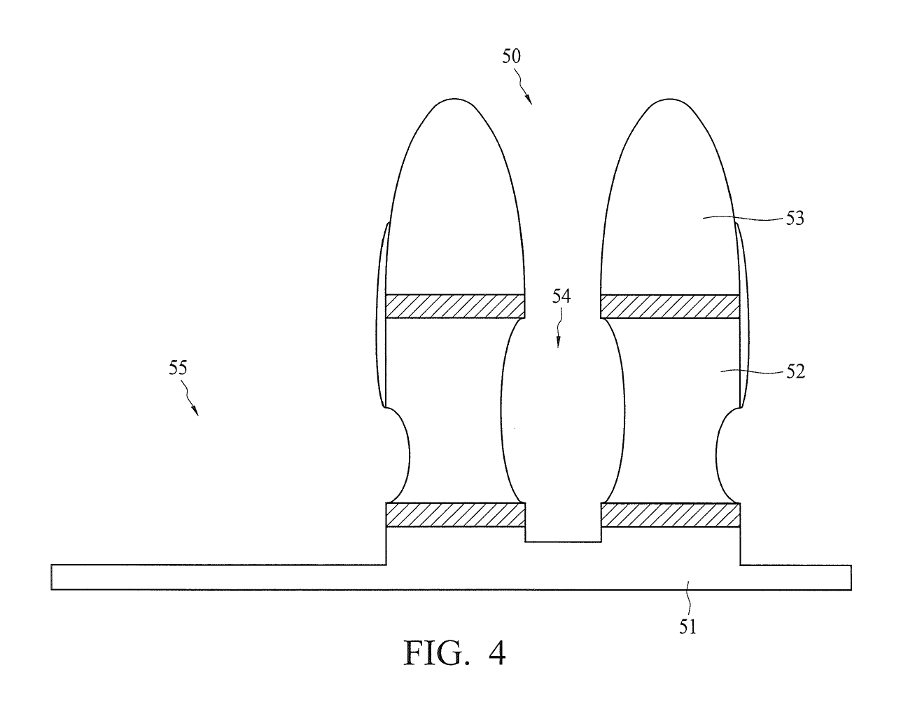

In some types of semiconductor fabrication, since the hard mask is used more than the photoresist, the photoresist occupation area is small, such that the supply amount of reactive products produced from the photoresist and ions such as Cl⁻ is small. As a result, side etching, side wall roughening, and the like occur on the sidewall portions of respective via structures 50 as shown in FIG. 4, when the etching system 1 in FIG. 1 is operated. The semiconductor substrate 51 is covered by a metal layer 52, on which a hard mask layer 53 is blanketed over.

In FIG. 4, the difference in etching removal amount (RIE-lag effect) is defined as difference of the etching amount between sparse patterns 55 and dense patterns 54. It is assumed that there is no etching rate difference between sparse patterns and dense patterns when the RIE-lag effect is 0 Å.

However, when a Cl₂ gas and a BCl₃ gas are used, side etching or side wall roughening of the etched film caused by Cl-type radicals cannot be prevented in conventional etching systems without the high-frequency power module 30. Therefore, it is necessary to suppress side etching and side wall roughening by introducing a deposition-type gas such as CHF₃ gas and thereby sputtering the photoresist and forming side wall protective films by CHCl-type and CCl-type reactions through the bias voltage having a pulse waveform.

Referring to FIG. 1 the deposition-type gas is introduced, through the flow controller 20 (C), into the processing container 10. The deposition-type gas is added at a flow rate of between 1% and 50% of a flow rate of the etching gas. The etching system 1 of FIG. 1 uses a deposition-type gas including at least two of C, H, and F, such as a CHF₃ gas, or a CF₄ gas. In another embodiment (not shown), when the etching gases are HBr gas, respectively, the deposition-type gas such as CF₄ gas is introduced into the processing container at a flow rate of between 1% and 45% of a flow rate of HBr gas.

The etching system 1 not only exhibits better performance than that of traditional RIE systems, but also provides improved etching characteristics by introducing the deposition-type gas including at least two of C, H, and F as the etching gas C as shown in FIG. 1.

In one embodiment, the etching system 1 of FIG. 1 is used, a voltage having a pulse waveform according to the invention is applied, and etching gases Cl₂, BCl₃, and CHF₃ are introduced. The sample 6 to be etched is a wafer for manufacture of semiconductor devices such as DRAMs or ASICs in which a film to be etched is composed of an aluminum-copper film etc., the photoresist occupation area is relatively small in the wafer surface, and the aspect ratio, that is (etching depth)/(width of interconnection opening), falls within a range of 0.5 to 25.0 at densest patterns of metal interconnections. The flow rates of the etching processing gases Cl2 and BCl3 are set at 80 standard cubic centimeters per minute (sccm) and 20 sccm, respectively. The processing pressure is set at 1.33 to 13.3 Pa (10 to 100 mTorr). The frequency of the pulse modulation is set at a value in a range of 1 Hz to 50 kHz and the duty ratio is set at a value in a range between 20% and 75%.

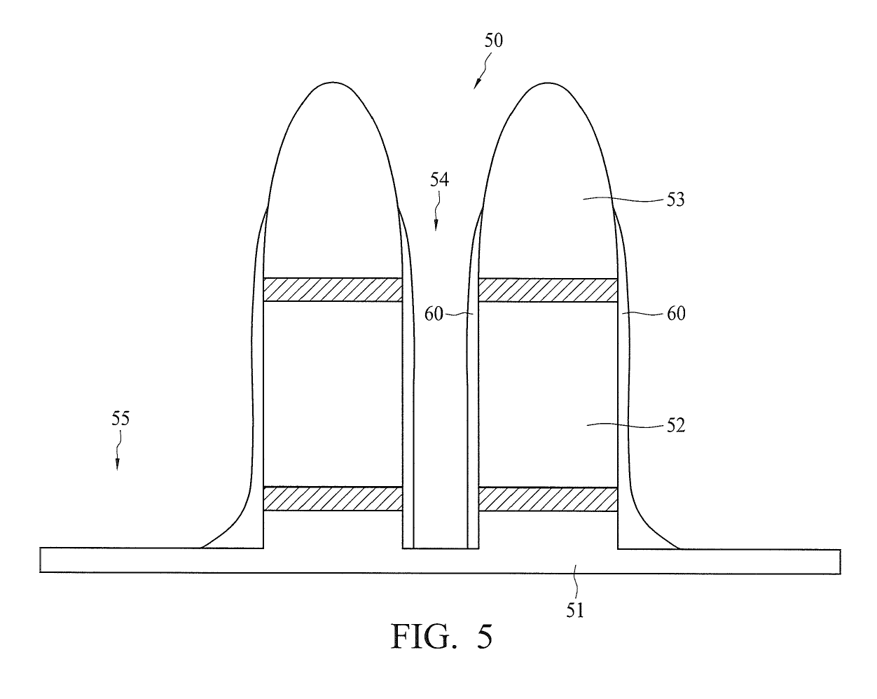

As seen from FIG. 5, the sidewall protecting film 60 increases in the via structure 50, and the RIE-lag effect decreases steeply. This is because reactive products produced from the deposition-type gas CHF₃ and ions such as Cl⁻ during power-on periods of a pulse-modulated voltage excessively react at sparse patterns, and thereby the etching rate difference between sparse patterns and dense patterns is reduced.

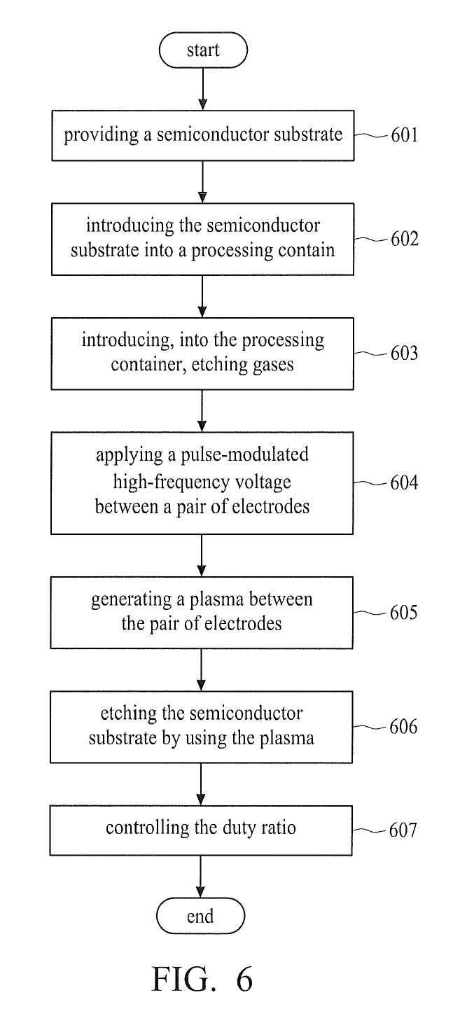

In conclusion, as shown in FIG. 6, the present invention provides a method for performing pulse-etching in a semiconductor device comprising the following steps: In step 601, a semiconductor substrate is provided. A metal layer is disposed on the semiconductor substrate, and a hard mask layer is blanketed over the metal layer and step 602 is executed. In step 602 the semiconductor substrate is introduced into a processing container and step 603 is executed. In step 603, etching gases are introduced into the processing container, wherein a deposition-type gas mixed with etching gases is composed of at least two of C, H, and F, and the etching gas includes a Cl₂ gas, a BCl₃ gas, an HBr gas and step 604 is executed. In step 604, a pulse-modulated high-frequency voltage is applied between a pair of electrodes that are provided in the processing container so as to be opposed to each other and to hold the semiconductor substrate, such that the high-frequency voltage is turned on and off to establish a duty ratio, and step 605 is executed. In step 605, a plasma is generated between the pair of electrodes, and step 606 is executed. In step 606, the semiconductor substrate is etched using the plasma, and step 607 is executed. In step 607 the duty ratio is controlled for reducing side-etchings, bowing trench effects, and RIE lag effect.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A system for performing pulse-etching in a semiconductor device, the system comprising:
a processing container, including:
a top wall and a bottom wall disposed corresponding to the top wall;
an evacuation outlet, disposed below the bottom wall;
a vacuum pressure setting valve, controlling the evacuation outlet for maintaining a vacuum pressure;
a pair of opposed electrodes, respectively disposed on the top wall and the bottom wall; and
a plurality of gas introduction inlets, disposed in the electrode disposed on the top wall, wherein the gas introduction inlets introduce an etching gas into a space between the top wall and the bottom wall;
at least one flow controller configured to control a flow rate of the etching gas; and
a high-frequency power module configured to apply a high-frequency voltage between the electrodes, such that the high-frequency voltage is turned on and off to establish a duty ratio.

2. The system of claim 1, wherein a deposition-type gas is added into the etching gas at a flow rate ranging between 1% and 50% of a flow rate of the etching gas.

3. The system of claim 1, wherein the high-frequency voltage is applied between the pair of electrodes and turned on and off at a modulation frequency in a range between 1 Hz and 50 kHz.

4. The system of claim 1, wherein a deposition-type gas, added into the etching gas, is selected from a CHF₃ gas, or a CF₄ gas.

5. The system of claim 1, wherein a deposition-type gas is added into the etching gas at a flow rate ranging between 1% and 45% of a flow rate of the etching gas including an HBr gas.

6. The system of claim 1, wherein the high-frequency voltage applied between the pair of electrodes is turned on and off with the duty ratio in a range between 20% and 75%.

7. A method for performing pulse-etching in a semiconductor device, the method comprising the steps of:
providing a semiconductor substrate, wherein a metal layer is disposed on the semiconductor substrate, and a hard mask layer is blanketed over the metal layer;
introducing the semiconductor substrate into a processing container;
introducing, into the processing container, etching gases in which a deposition-type gas composed of at least two of C, H, and F is added to etching gas selected from the group consisting of Cl₂ gas, BCl₃ gas, HBr gas, and the combination thereof;
applying a pulse-modulated high-frequency voltage between a pair of electrodes that are provided in the processing container so as to be opposed to each other and to hold the semiconductor substrate, such that the high-frequency voltage is turned on and off to establish a duty ratio;
generating a plasma between the pair of electrodes; and
etching the semiconductor substrate using the plasma.

8. The method of claim 7, wherein the deposition-type gas is added at a flow rate ranging between 1% and 50% of a flow rate of the etching gas.

9. The method of claim 7, wherein the high-frequency voltage is applied between the pair of electrodes and turned on and off at a modulation frequency in a range between 1 Hz and 50 kHz.

10. The method of claim 7, wherein the deposition-type gas is selected from a CHF₃ gas, or a CF₄ gas.

11. The method of claim 7, wherein the deposition-type gas is added at a flow rate ranging between 1% and 45% of a flow rate of HBr gas.

12. method of claim 7, wherein the high-frequency voltage applied between the pair of electrodes is turned on and off with the duty ratio in a range between 20% and 75%.
